(19) United States
(12) Patent Application Publication
(10) Pub. No.: US 2026/0104477 A1
(43) Pub. Date: Apr. 16, 2026

(54) MAGNETIC SENSOR

(71) Applicant: TDK CORPORATION, Tokyo (JP)

(72) Inventors: Takafumi KOBAYASHI, Tokyo (JP); Tetsuya Hiraki, Tokyo (JP); Norikazu Ota, Tokyo (JP); Tsuyoshi Umehara, Tokyo (JP)

(73) Assignee: TDK CORPORATION, Tokyo (JP)

(21) Appl. No.: 19/348,991

(22) Filed: Oct. 3, 2025

(30) Foreign Application Priority Data
Oct. 11, 2024 (JP) 2024-178731

(51) Int. Cl. G01R 33/09

(52) U.S. Cl. CPC G01R 33/09

(57) ABSTRACT

A magnetic sensor includes a plurality of first MR elements and a plurality of second MR elements. Each plurality of first MR elements and the plurality of second MR elements has a resistance value change characteristic where a resistance value changes in accordance with a stable state of magnetic vortex structure, under same strength of an applied magnetic field. A statistical distribution of resistance change amount of plurality of first MR elements forms a first distribution centered on a first value. A statistical distribution of a resistance change amount of the plurality of second MR elements forms a second distribution centered on a second value. A group including the plurality of first MR elements and the plurality of second MR elements has a characteristic where a statistical distribution of a resistance change amount forms a third distribution centered on a third value between the first value and the second value.

### CROSS REFERENCE TO RELATED APPLICATIONS

This application claims the benefit of Japanese Priority Patent Application No. 2024-178731 filed on Oct. 11, 2024, the entire contents of which are incorporated herein by reference.

### BACKGROUND

The disclosure relates to a magnetic sensor including a plurality of magnetoresistive elements each including a free layer configured to have a magnetic vortex structure.

In recent years, magnetic sensors have been used for a variety of applications. Examples of known magnetic sensors include one that uses a spin-valve magnetoresistive element provided on a substrate. The spin-valve magnetoresistive element includes a magnetization pinned layer in which a direction of magnetization is fixed, a free layer in which a direction of magnetization can be changed in accordance with a direction of an applied magnetic field, and a gap layer arranged between the magnetization pinned layer and the free layer.

U.S. Patent Application Publication No. 2023/0324477 discloses a magnetic sensor device including a plurality of tunneling magnetoresistance (TMR) elements. The TMR element includes a free layer having a disk-like shape. A magnetization pattern having a closed magnetic flux, which is also referred to as a vortex state, is spontaneously formed in the free layer. In a magnetoresistive element including a free layer having a magnetic vortex structure as described in U.S. Patent Application Publication No. 2023/0324477, the center of the magnetic vortex structure moves in accordance with a magnetic field being a detection target, whereby the resistance value of the magnetoresistive element changes.

In the free layer having a magnetic vertex structure, the direction of magnetization in a stable state may be a clockwise direction or a counterclockwise direction. Ideally, the resistance value of the magnetoresistive element changes in the same manner in either case. However, in actuality, the resistance value of the magnetoresistive element may differ due to the structure of the magnetoresistive element or the like.

In the magnetic sensor, there may be a case in which an external magnetic field, which is not the magnetic field being a detection target and magnetically saturate the free layer, is temporarily applied. In the free layer having a magnetic vortex structure, the direction of magnetization in the stable state may be reversed after such an external magnetic field is applied. As a result, the characteristics of the magnetic sensor may vary before and after the application of the external magnetic field.

### SUMMARY

A magnetic sensor according to an embodiment of a first aspect of the disclosure is configured to detect a magnetic field of a detection target to generate a detection signal, and includes a plurality of first magnetoresistive elements and a plurality of second magnetoresistive elements. The plurality of first magnetoresistive elements and the plurality of second magnetoresistive elements are electrically connected to each other. Each of the plurality of first magnetoresistive elements and the plurality of second magnetoresistive elements includes a magnetization pinned layer in which a direction of magnetization is fixed and a free layer configured to have a magnetic vortex structure and move a center of the magnetic vortex structure in accordance with an applied magnetic field, and has a resistance value change characteristic where a resistance value changes in accordance with a stable state of the magnetic vortex structure, under the same strength of the applied magnetic field. A first group being a group of the plurality of first magnetoresistive elements has a characteristic where a statistical distribution of a resistance change amount forms a first distribution centered on a first value, the resistance change amount being a parameter associated with the resistance value change characteristic. A second group being a group of the plurality of second magnetoresistive elements has a characteristic where the statistical distribution of the resistance change amount forms a second distribution centered on a second value different from the first value. A third group being a group including the plurality of first magnetoresistive elements and the plurality of second magnetoresistive elements has a characteristic where the statistical distribution of the resistance change amount forms a third distribution centered on a third value between the first value and the second value.

A magnetic sensor according to an embodiment of a second aspect of the disclosure is configured to detect a magnetic field of a detection target to generate a detection signal, and includes a plurality of magnetoresistive elements. Each of the plurality of magnetoresistive elements includes a magnetization pinned layer in which a direction of magnetization is fixed and a free layer configured to have a magnetic vortex structure and move a center of the magnetic vortex structure in accordance with an applied magnetic field, and has a resistance value change characteristic where a resistance value changes in accordance with a stable state of the magnetic vortex structure, under the same strength of the applied magnetic field. A group of the plurality of magnetoresistive elements has a characteristic where a statistical distribution of a resistance change amount forms a distribution centered on a specific value, the resistance change amount being a parameter associated with the resistance value change characteristic. Each of the plurality of magnetoresistive elements is configured so that the free layer is not magnetically saturated when the strength of the magnetic field being the detection target falls within a first range. The detection signal changes within a second range when a strength of the magnetic field being the detection target changes within the first range. The group has a characteristic where, as the number of the plurality of magnetoresistive elements is increased, a statistical distribution of the resistance change amount of a resistor section approaches a normal distribution, and a standard deviation of the distribution is reduced, the resistor section being configured by electrically connecting the plurality of magnetoresistive elements to each other. The number of the plurality of magnetoresistive elements is defined as a number at which a change amount is equal to or less than 5% of a difference between a maximum value and a minimum value of the second range, the change amount being a change amount of the detection signal before and after temporary application of an external magnetic field that magnetically saturates the free layer to the plurality of magnetoresistive elements and a change amount of the detection signal when the strength of the magnetic field being the detection target is a specific strength within the first range.

Objects, features, and advantages of the disclosure appear more fully from the following description.

### BRIEF DESCRIPTION OF THE DRAWINGS

The accompanying drawings are included to provide an understanding of the disclosure and are incorporated in and constitute a part of this specification. The drawings illustrate example embodiments and, together with the specification, serve to explain the principles of the technology.

FIG. 1 is a plan view showing a magnetic sensor according to a first example embodiment of the disclosure.

FIG. 2 is a circuit diagram showing a circuit configuration of the magnetic sensor according to the first example embodiment of the disclosure.

FIG. 3 is a plan view showing a part of a resistor section in the first example embodiment of the disclosure.

FIG. 4 is a plan view showing a part of an element array in the first example embodiment of the disclosure.

FIG. 5 is a perspective view showing a magnetoresistive element in the first example embodiment of the disclosure.

FIG. 6 is a plan view showing a free layer of the magnetoresistive element in the first example embodiment of the disclosure.

FIG. 7 is a plan view showing the free layer when a target magnetic field is applied to the magnetoresistive element in the first example embodiment of the disclosure.

FIG. 8 is a plan view showing the free layer when the target magnetic field is applied to the magnetoresistive element in the first example embodiment of the disclosure.

FIG. 9 is an explanatory diagram showing a relationship between a strength of a magnetic field component and magnitude of magnetization of the entire free layer in the first example embodiment of the disclosure.

FIG. 10A, FIG. 10B, and FIG. 10C are plan views schematically showing magnetization of a local part of a magnetization pinned layer and magnetization of the free layer of the magnetoresistive element in the first example embodiment of the disclosure.

FIG. 11 is an explanatory diagram showing a relationship between a strength of a magnetic field component and a resistance value of the magnetoresistive element in the first example embodiment of the disclosure.

FIG. 12 is an explanatory diagram showing a statistical distribution of a resistance change amount for each of first to third groups in the first example embodiment of the disclosure.

FIG. 13 is an explanatory diagram showing a statistical distribution of a resistance change amount of the resistor section in the first example embodiment of the disclosure.

FIG. 14 is a plan view showing an example of a layout of the magnetoresistive elements in the first example embodiment of the disclosure.

FIG. 15 is a plan view showing the free layer to which a structure in the first example embodiment of the disclosure is added.

FIG. 16 is a plan view showing the free layer having a planar shape that can control a direction of magnetization in the first example embodiment of the disclosure.

FIG. 17 is a plan view showing a first structure that controls directions of magnetization of the MR element and the free layer in the first example embodiment of the disclosure.

FIG. 18 is a plan view showing a second structure that controls directions of magnetization of the MR element and the free layer in the first example embodiment of the disclosure.

FIG. 19 is an explanatory diagram schematically showing a direction of an electric current flowing through the magnetoresistive element in the first example embodiment of the disclosure.

FIG. 20 is an explanatory diagram schematically showing a magnetic field generated due to the electric current flowing through the magnetoresistive element in the first example embodiment of the disclosure.

FIG. 21 is a plan view showing a first modification example of the magnetic sensor according to the first example embodiment of the disclosure.

FIG. 22 is a plan view showing a second modification example of the magnetic sensor according to the first example embodiment of the disclosure.

FIG. 23 is a plan view showing a third modification example of the magnetic sensor according to the first example embodiment of the disclosure.

FIG. 24 is a side view showing a magnetoresistive element and a shield in a second example embodiment of the disclosure.

FIG. 25 is an explanatory diagram showing a relationship between a strength of a magnetic field component and a detection signal in the second example embodiment of the disclosure.

### DETAILED DESCRIPTION

An object of the disclosure is to provide a magnetic sensor that can suppress variation in characteristics caused by a direction of magnetization of a free layer configured to have a magnetic vortex structure.

In the following, some example embodiments and modification examples of the disclosure are described in detail with reference to the accompanying drawings. Note that the following description is directed to illustrative examples of the disclosure and not to be construed as limiting the technology. Elements including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional, and may be provided on an as-needed basis. The drawings are schematic and are not intended to be drawn to scale. Similar elements are denoted with the same reference numerals to avoid redundant descriptions.

### First Example Embodiment

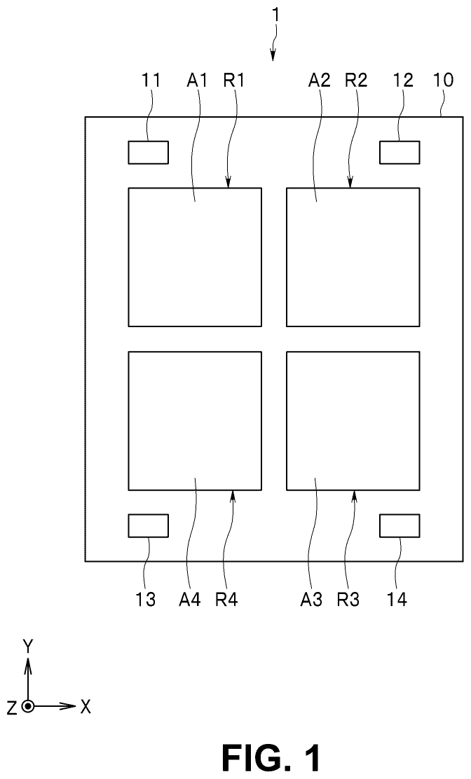

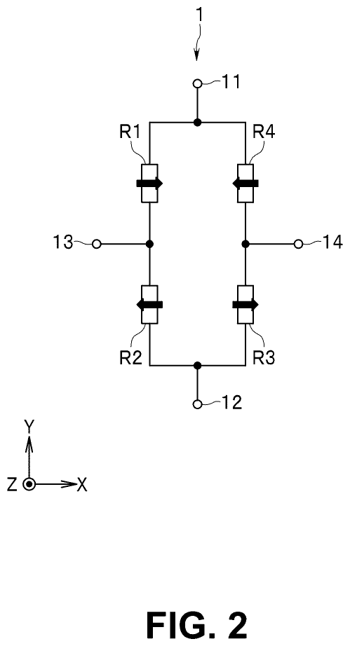

First, with reference to FIG. 1 and FIG. 2, a schematic configuration of a magnetic sensor according to a first example embodiment of the disclosure is described. FIG. 1 is a plan view showing a magnetic sensor 1 according to the example embodiment. FIG. 2 is a circuit diagram showing a circuit configuration of the magnetic sensor 1 according to the example embodiment.

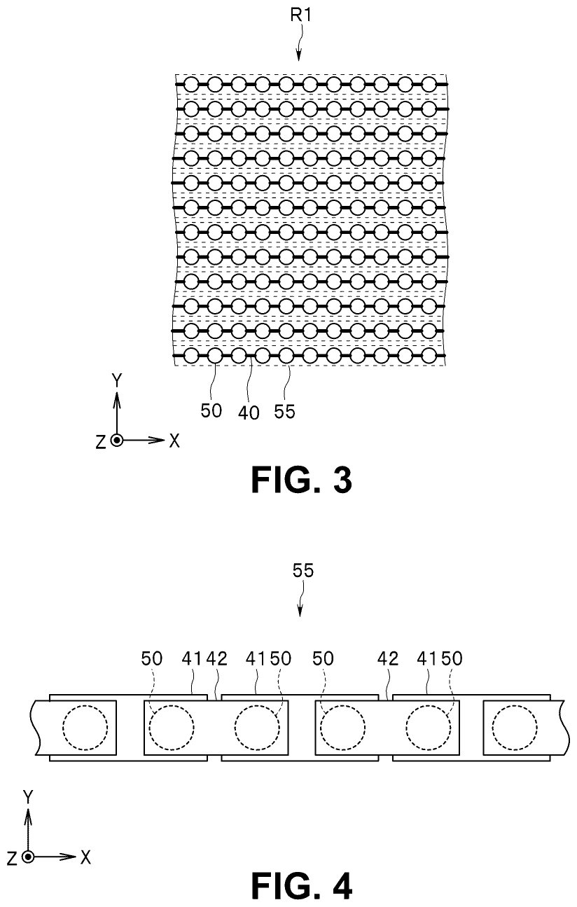

The magnetic sensor 1 in the example embodiment includes a plurality of magnetoresistive elements (hereinafter, referred to as MR elements) 50. Each of the MR elements 50 is configured so that a resistance value changes in accordance with a target magnetic field being a magnetic field of a detection target of the magnetic sensor 1. Note that the MR element 50 is shown in FIG. 3 and the like described below.

The magnetic sensor 1 further includes a power supply terminal 11, a ground terminal 12, a first output terminal 13, a second output terminal 14, a first resistor section R1, a second resistor section R2, a third resistor section R3, and a fourth resistor section R4. Each of the power supply terminal 11, the ground terminal 12, the first output terminal 13, and the second output terminal 14 is configured by an electrode layer formed of a conductive material. Each of the first resistor section R1 to the fourth resistor section R4 includes a plurality of MR elements 50 among the plurality of MR elements 50.

As shown in FIG. 2, the first resistor section R1 is provided between the power supply terminal 11 and the first output terminal 13 in the circuit configuration. The second resistor section R2 is provided between the ground terminal 12 and the first output terminal 13 in the circuit configuration. The third resistor section R3 is provided between the ground terminal 12 and the second output terminal 14 in the circuit configuration. The fourth resistor section R4 is provided between the power supply terminal 11 and the second output terminal 14 in the circuit configuration. Note that, in the application, the expression “in the (a) circuit configuration” is used to indicate a layout in a circuit diagram, not a layout in a physical configuration.

A voltage or an electric current having a specific magnitude is applied to the power supply terminal 11. The ground terminal 12 is connected to the ground.

As shown in FIG. 1, the magnetic sensor 1 further includes a substrate 10. The power supply terminal 11, the ground terminal 12, the first output terminal 13, and the second output terminal 14 are provided on the substrate 10.

Here, as shown in FIG. 1, an X direction, a Y direction, and a Z direction are defined. The X direction, the Y direction, and the Z direction are orthogonal to one another. The opposite directions to the X, Y, and Z directions are expressed as −X, −Y, and −Z directions, respectively. In the example embodiment, in particular, a direction perpendicular to the surface of the substrate 10 is referred to as the Z direction.

As used herein, the term “above” refers to positions located ahead a certain reference position in the Z direction, and “below” refers to positions opposite from the “above” positions with respect to the certain reference position. For each component of the magnetic sensor 1, a surface located at an end in the Z direction is referred to as an “upper surface”, and a surface located at an end in the −Z direction is referred to as a “lower surface”. The expression “as viewed in a specific direction (for example, the Z direction)” indicates that a target object is viewed from a position away in the specific direction or in one direction parallel to the specific direction.

The substrate 10 includes element layout regions A1, A2, A3, and A4. In the example embodiment, the element layout regions A1 to A4 are defined as planar regions parallel to the XY plane. Each of the plurality of MR elements 50 is arranged so as to overlap with any one of the element layout regions A1 to A4 as viewed in the Z direction. In the example embodiment, for the sake of convenience, it is assumed that the element layout regions A1 to A4 are on the upper surface of the substrate 10.

The plurality of MR elements 50 are arranged in a distributed manner in the element layout regions A1 to A4. The plurality of MR elements 50 forming the first resistor section R1 are arranged in the element layout region A1. The plurality of MR elements 50 forming the second resistor section R2 are arranged in the element layout region A2. The plurality of MR elements 50 forming the third resistor section R3 are arranged in the element layout region A3. The plurality of MR elements 50 forming the fourth resistor section R4 are arranged in the element layout region A4.

In the example shown in FIG. 1, the element layout region A2 is arranged ahead the element layout region A1 in the X direction. The element layout region A3 is arranged ahead the element layout region A2 in the −Y direction. The element layout region A4 is arranged ahead the element layout region A3 in the −X direction, and is arranged ahead the element layout region A1 in the −Y direction.

Note that the layout of the power supply terminal 11, the ground terminal 12, the first output terminal 13, the second output terminal 14, and the element layout regions A1 to A4 (the first resistor section R1 to the fourth resistor section R4) is not limited to the example shown in FIG. 1. For example, the element layout regions A1 to A4 may be arranged in an arbitrary order along a direction parallel to the X direction or a direction parallel to the Y direction.

Next, with reference to FIG. 3 and FIG. 4, a specific structure of the first resistor section R1 to the fourth resistor section R4 is described in detail. Here, the first resistor section R1 is described as an example. FIG. 3 is a plan view showing a part of the first resistor section R1. FIG. 4 is a plan view showing a part of an element array. In FIG. 3 and FIG. 4, a plurality of circles represent the plurality of MR elements 50.

The first resistor section R1 may include a plurality of element arrays 55. Each of the plurality of element arrays 55 may include a wiring line 40 and a plurality of MR elements 50, which are connected in series to each other by the wiring line 40, among the plurality of MR elements 50. The plurality of element arrays 55 may be connected in series to each other, or may be connected in parallel to each other by two terminals, which are omitted in illustration.

The wiring line 40 includes a plurality of lower electrodes 41 and a plurality of upper electrodes 42. Each of the lower electrodes 41 has an elongated shape. A gap is formed between the two lower electrodes 41 that are adjacent to each other with an interval. On the upper surface of the lower electrode 41, the MR element 50 is arranged in the vicinity of each of both ends of the lower electrode 41 in a longitudinal direction. Each of the upper electrodes 42 has an elongated shape, and is arranged so as to overlap with the two adjacent MR elements 50 arranged on the two lower electrodes 41 that are adjacent to each other with an interval, as viewed in the Z direction.

In the example shown in FIG. 3 and FIG. 4, at least a part of each of the plurality of element arrays 55 extends in a direction parallel to the X direction. Therefore, in at least a part of each of the plurality of element arrays 55, the plurality of MR elements 50 are arrayed in a direction parallel to the X direction. In at least a part of each of the plurality of element arrays 55, each of the plurality of lower electrodes 41 and the plurality of upper electrodes 42 has a shape elongated in a direction parallel to the X direction.

Note that the shape of each of the plurality of element arrays 55 is not limited to the example shown in FIG. 3 and FIG. 4. For example, each of the plurality of element arrays 55 may extend in an arbitrary direction other than a direction parallel to the X direction. Alternatively, each of the plurality of element arrays 55 may include a plurality of parts extending in directions different from each other.

The first resistor section R1 is described above as an example. The description on the first resistor section R1 given above is also applied to the second resistor section R2 to the fourth resistor section R4.

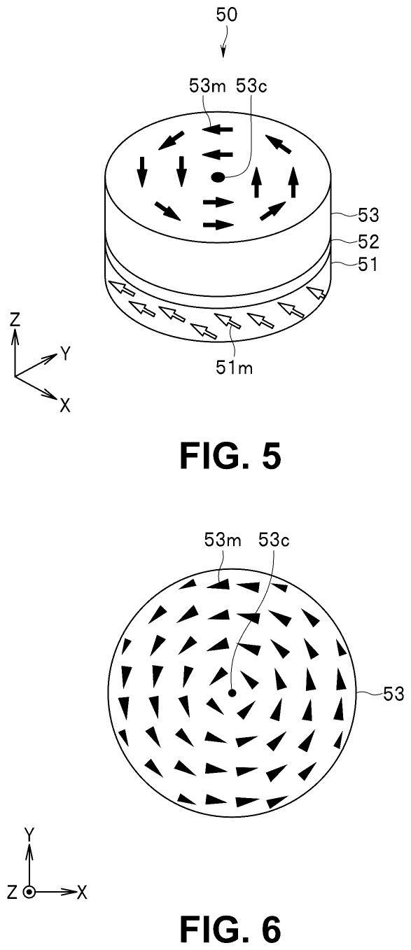

Next, with reference to FIG. 5 and FIG. 6, a configuration of the MR element 50 is described. FIG. 5 is a perspective view showing the MR element 50. FIG. 6 is a plan view showing the free layer of the MR element 50.

The MR element 50 includes a magnetization pinned layer 51 in which a direction of magnetization 51m is fixed, a free layer 53, and a gap layer 52 arranged between the magnetization pinned layer 51 and the free layer 53. The material and shape of the free layer 53 are selected so as to have a magnetic vortex structure (also referred to as a vortex structure). The gap layer 52 is a tunnel barrier layer or a nonmagnetic conductive layer.

The free layer 53 has a columnar shape or a substantially columnar shape. The free layer 53 has the magnetization 53m that forms a vortex pattern centered around the magnetic vortex structure center 53c. When there is no magnetic field applied to the MR element 50, the magnetic vortex structure center 53c matches with or substantially matches with the axis of the column. The free layer 53 is configured so that the magnetic vortex structure center 53c can move in accordance with a target magnetic field MF. Note that, in the example shown in FIG. 5 and FIG. 6, the entire MR element 50 has a columnar shape.

The magnetic vortex structure center 53c moves when a component, which is in a direction orthogonal to the Z direction, of the target magnetic field MF is applied to the free layer 53. Within the range of change in the strength of the component, it is preferred that the free layer 53 is not magnetically saturated.

In the example embodiment, the magnetization 51m of the magnetization pinned layer 51 includes a component in a direction parallel to the X direction. Note that, when the magnetization 51m of the magnetization pinned layer 51 includes a component in a specific direction, the component in the specific direction may be the main component of the magnetization 51m of the magnetization pinned layer 51. In the example embodiment, when the magnetization 51m of the magnetization pinned layer 51 includes the component in the specific direction, the direction of the magnetization 51m of the magnetization pinned layer 51 is the same or substantially the same as the specific direction.

The MR element 50 may further include an antiferromagnetic layer. The antiferromagnetic layer is formed of an antiferromagnetic material, and is in exchange coupling with the magnetization pinned layer 51 to thereby fix the direction of the magnetization 51m of the magnetization pinned layer 51. Alternatively, the magnetization pinned layer 51 may be a so-called self-pinned layer (Synthetic Ferri Pinned layer, SFP layer). The self-pinned layer has a stacked ferri structure in which a ferromagnetic layer, a nonmagnetic intermediate layer, and a ferromagnetic layer are stacked, and the two ferromagnetic layers are antiferromagnetically coupled.

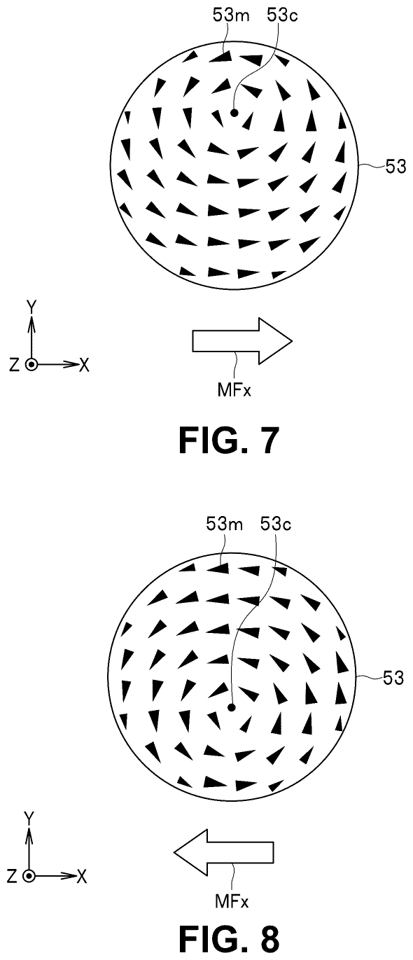

Here, the resistance value of the MR element 50 is described while focusing on a case in which the direction of the magnetization 51m of the magnetization pinned layer 51 is the −X direction, as an example. FIG. 7 and FIG. 8 show the free layer 53 when a magnetic field component MFx, which is in a direction parallel to the X direction, of the target magnetic field MF is applied to the free layer 53.

FIG. 7 shows the free layer 53 when the direction of the magnetic field component MFx is the X direction. In this case, the magnetic vortex structure center 53c moves due to the magnetic field component MFx, and an amount of the magnetization 53m oriented in the X direction is more than an amount of the magnetization 53m oriented in the −X direction. In this case, the resistance value of the MR element 50 is increased.

FIG. 8 shows the free layer 53 when the direction of the magnetic field component MFx is the −X direction. In this case, the magnetic vortex structure center 53c moves due to the magnetic field component MFx, and the amount of the magnetization 53m oriented in the −X direction is more than the amount of the magnetization 53m oriented in the X direction. In this case, the resistance value of the MR element 50 is reduced.

A change amount of the resistance value of the MR element 50 depends on the strength of the magnetic field component MFx. In a case in which the direction of the magnetic field component MFx is the X direction, when the strength of the magnetic field component MFx is increased, the amount of the magnetization 53m oriented in the X direction is increased. The resistance value of the MR element 50 is increased as the amount of the magnetization 53m oriented in the X direction is increased. In a case in which the direction of the magnetic field component MFx is the −X direction, when the strength of the magnetic field component MFx is increased, the amount of the magnetization 53m oriented in the −X direction is increased. The resistance value of the MR element 50 is reduced as the amount of the magnetization 53m oriented in the −X direction is increased. As the strength of the magnetic field component MFx is increased, the resistance value of the MR element 50 changes so that an increase amount or a reduction amount thereof is increased. As the strength of the magnetic field component MFx is reduced, the resistance value of the MR element 50 changes so that an increase amount or a reduction amount thereof is reduced. In the example embodiment, in particular, the relationship between the strength of the magnetic field component MFx and the resistance value of the MR element 50 is a linear relationship or a substantially linear relationship as long as a condition where the free layer 53 is not saturated is satisfied.

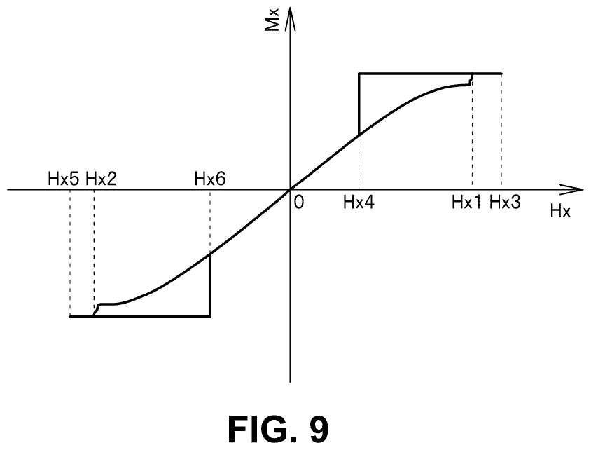

Next, with reference to FIG. 9, a relationship between the strength of the magnetic field component MFx and a magnitude of magnetization of the entire free layer 53 is described. FIG. 9 is a characteristic diagram schematically showing the relationship between the strength of the magnetic field component MFx and the magnitude of the magnetization of the entire free layer 53. In FIG. 9, the horizontal axis represents a strength Hx of the magnetic field component MFx, and the vertical axis represents a magnetization magnitude Mx of the entire free layer 53. In FIG. 9, the strength Hx when the direction of the magnetic field component MFx is the X direction is represented by a positive value, and the strength Hx when the direction of the magnetic field component MFx is the −X direction is represented by a negative value. In a case in which the direction of the magnetic field component MFx is the X direction, when the amount of the magnetization 53m oriented in the X direction is increased, the magnetization magnitude Mx of the entire free layer 53 is increased. In a case in which the direction of the magnetic field component MFx is the −X direction, when the amount of the magnetization 53m oriented in the −X direction is increased, the magnetization magnitude Mx of the entire free layer 53 is reduced.

First, description is made on a case in which the strength Hx is increased from 0. When the strength Hx is gradually increased from 0, the magnetization magnitude Mx is gradually increased. When the strength Hx is equal to or greater than a value Hx1, the magnetization magnitude Mx is constant, and the free layer 53 is magnetically saturated.

Next, description is made on a case in which the strength Hx is reduced from 0. When the strength Hx is gradually reduced from 0, the magnetization magnitude Mx is also gradually reduced. When the strength Hx is equal to or less than a value Hx2, the magnetization magnitude Mx is constant, and the free layer 53 is magnetically saturated.

As shown in FIG. 9, within a specific range where the strength Hx is greater than the value Hx2, and is less than the value Hx1, the magnetization magnitude Mx changes linearly with respect to the change of the strength Hx. Note that the expression “to linearly change” indicates that the magnetization magnitude Mx changes linearly or substantially linearly with respect to the change of the strength Hx in the characteristic diagram showing the relationship between the strength Hx and the magnetization magnitude Mx.

In the example embodiment, within the change range of the strength Hx, it is preferred that the free layer 53 is not magnetically saturated while the magnetization magnitude Mx linearly changes with respect to the change of the strength Hx.

Note that, when the strength Hx is greater than the value Hx1 and the free layer 53 is magnetically saturated, and thereafter the strength Hx is reduced from a value Hx3 greater than the value Hx1, there is less change in the magnetization magnitude Mx until the strength Hx reaches a value Hx4 less than the value Hx1. When the strength Hx is less than the value Hx4, the magnetization magnitude Mx linearly changes with respect to the change of the strength Hx similarly to a case in which the strength Hx changes within the specific range from the value Hx2 to the value Hx1.

Similarly, when the strength Hx is less than the value Hx2 and the free layer 53 is magnetically saturated, and thereafter the strength Hx is increased from a value Hx5 less than the value Hx2, there is less change in the magnetization magnitude Mx until the strength Hx reaches a value Hx6 greater than the value Hx2. When the strength Hx is greater than the value Hx6, the magnetization magnitude Mx linearly changes with respect to the change of the strength Hx similarly to a case in which the strength Hx changes within the specific range from the value Hx2 to the value Hx1.

Although not shown, the relationship between the strength Hx and the resistance value of the MR element 50 is similar to the relationship between the strength Hx and the magnitude of the magnetization of the free layer 53.

Next, with reference to FIG. 2, the direction of the magnetization 51m of the magnetization pinned layer 51 in each of the first resistor section R1 to the fourth resistor section R4 is described. The magnetization 51m of the magnetization pinned layer 51 of each of the plurality of MR elements 50 in the first resistor section R1 includes a component in a first magnetization direction. The magnetization 51m of the magnetization pinned layer 51 of each of the plurality of MR elements 50 in the second resistor section R2 includes a component in a second magnetization direction opposite to the first magnetization direction. The magnetization 51m of the magnetization pinned layer 51 of each of the plurality of MR elements 50 in the third resistor section R3 includes a component in the first magnetization direction. The magnetization 51m of the magnetization pinned layer 51 of each of the plurality of MR elements 50 in the fourth resistor section R4 includes a component in the second magnetization direction. In FIG. 2, the two arrows that are illustrated in the first resistor section R1 and the third resistor section R3 represent the first magnetization direction. In FIG. 2, the two arrows that are illustrated in the second resistor section R2 and the fourth resistor section R4 represent the second magnetization direction. In the example embodiment, in particular, the first magnetization direction is the X direction, and the second magnetization direction is the −X direction.

Next, with reference to FIG. 2, at least one detection signal generated by the magnetic sensor 1 is described. When the direction of the magnetic field component MFx is the X direction, the resistance value of each of the plurality of MR elements 50 of the first resistor section R1 and the third resistor section R3 is reduced, and the resistance value of each of the plurality of MR elements 50 of the second resistor section R2 and the fourth resistor section R4 is increased, as compared to a state in which there is no magnetic field MFx. As a result, the resistance value of each of the first resistor section R1 and the third resistor section R3 is reduced, and the resistance value of each of the second resistor section R2 and the fourth resistor section R4 is increased.

When the direction of the magnetic field component MFx is the −X direction, the change in the resistance value of each of the first resistor section R1 to the fourth resistor section R4 is opposite to that in the above-described case in which the direction of the magnetic field component MFx is the X direction.

As described above, when the direction and the strength of the magnetic field component MFx change, the resistance value of each of the first resistor section R1 to the fourth resistor section R4 changes so that the resistance value of each of the first resistor section R1 and the third resistor section R3 is increased while the resistance value of each of the second resistor section R2 and the fourth resistor section R4 is reduced, or the resistance value of each of the first resistor section R1 and the third resistor section R3 is reduced while the resistance value of each of the second resistor section R2 and the fourth resistor section R4 is increased. With this, a potential of a connection point between the first resistor section R1 and the second resistor section R2, in other words, a potential of the first output terminal 13, and a potential of a connection point between the third resistor section R3 and the fourth resistor section R4, in other words, a potential of the second output terminal 14 change. The magnetic sensor 1 may generate a signal corresponding to the potential of the first output terminal 13 and a signal corresponding to the potential of the second output terminal 14, as detection signals. Alternatively, the magnetic sensor 1 may generate a signal corresponding to a potential difference between the first output terminal 13 and the second output terminal 14, as a detection signal. In this case, the magnetic sensor 1 may further include a differential amplifier (differential detector) that outputs the signal corresponding to the potential difference between the first output terminal 13 and the second output terminal 14, as the detection signal.

Next, a manufacturing method for the magnetic sensor 1 according to the example embodiment is briefly described. The manufacturing method for the magnetic sensor 1 includes a step of forming the plurality of MR elements 50 on the substrate 10. In the step of forming the plurality of MR elements 50, first, a plurality of initial MR elements that later serve as the plurality of MR elements 50 are formed. Each of the plurality of initial MR elements includes at least an initial magnetization pinned layer to later serve as the magnetization pinned layer 51, the free layer 53, and the gap layer 52.

Next, the direction of the magnetization of the initial magnetization pinned layer is fixed in a specific direction by using laser light and external magnetic fields in the foregoing specific directions. For example, the plurality of initial MR elements that later serve as the plurality of MR elements 50 of the first resistor section R1 the third resistor section R3 are irradiated with laser light while an external magnetic field in the first magnetization direction (X direction) is applied thereto. When the initial MR element includes the antiferromagnetic layer, the irradiation of the laser light is performed so that the temperature of the plurality of initial MR elements irradiated with the laser light is equal to or higher than a blocking temperature of the antiferromagnetic layer. The temperature of the plurality of initial MR elements can be adjusted, for example, by the intensity and the pulse width of the laser light. After the irradiation of the laser light, when the temperature of the plurality of initial MR elements becomes lower than the blocking temperature, the direction of the magnetization of the initial magnetization pinned layer is fixed in the first magnetization direction. With this, the initial magnetization pinned layer serves as the magnetization pinned layer 51, and the plurality of initial MR elements serve as the plurality of MR elements 50 of the first resistor section R1 and the third resistor section R3.

In the other plurality of initial MR elements that later serve as the plurality of MR elements 50 of the second resistor section R2 and the fourth resistor section R4, the direction of the external magnetic field is set to the second magnetization direction (−X direction). With this, the direction of the magnetization of the initial magnetization pinned layer of each of the other plurality of initial MR elements can be fixed to the second magnetization direction. In this manner, the plurality of MR elements 50 of the second resistor section R2 and the fourth resistor section R4 are thus formed.

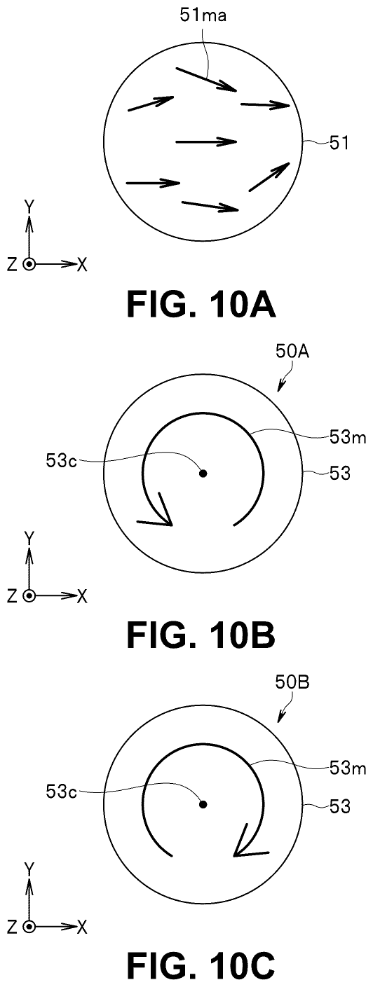

Next, with reference to FIGS. 10A to 10C, the direction of the magnetization 53m of the free layer 53 and the characteristic based on the direction of the magnetization 53m are described. Here, description is made on a case in which the magnetization 51m of the magnetization pinned layer 51 includes a component in the first magnetization direction, in other words, the X direction, as an example. FIG. 10A is an explanatory diagram schematically showing magnetization of a local part of the magnetization pinned layer 51. FIG. 10B and FIG. 10C are explanatory diagrams schematically showing the magnetization 53m of the free layer 53.

As shown in FIG. 10B and FIG. 10C, the free layer 53 has two stable states. The free layer 53 shown in FIG. 10B may be stable under a state in which the direction of the magnetization 53m is along a first direction (a counterclockwise direction in FIG. 10B) around the magnetic vortex structure center 53c, as viewed in the stacking direction of the magnetization pinned layer 51 and the free layer 53, in other words, the Z direction. The free layer 53 shown in FIG. 10C may be stable under a state in which the direction of the magnetization 53m is along a second direction (a clockwise direction in FIG. 10C) opposite to the first direction around the magnetic vortex structure center 53c, as viewed in the Z direction. Hereinafter, a state of the free layer 53 in which the direction of the magnetization 53m of the free layer 53 is stable along the first direction is referred to as a first state, and a state of the free layer 53 in which the direction of the magnetization 53m of the free layer 53 is stable along the second direction is referred to as a second state.

Incidentally, FIG. 10A shows the magnetization pinned layer 51 that is formed so that the magnetization 51m of the magnetization pinned layer 51 includes a component in the first magnetization direction, in other words, the X direction. When the direction of the magnetization 51m of the entire magnetization pinned layer 51 is the X direction, ideally, a direction of a magnetization 51ma of each of a plurality of local parts of the magnetization pinned layer 51 is also the X direction. However, in actuality, due to variations in factors such as a crystal state at an interface, crystalline magnetic anisotropy, or shape magnetic anisotropy, the direction of the magnetization 51ma is dispersed to some extent. Thus, in actuality, the magnetization 51m of the magnetization pinned layer 51 includes a plurality of components with directions different from each other. When the direction of the magnetization 51ma is dispersed, the resistance value of the MR element 50 may differ depending on whether the stable state of the free layer 53 is the first state or the second state.

In the magnetic sensor 1, there may be a case in which an external magnetic field, which is not the magnetic field being a detection target and magnetically saturate the free layer 53, is temporarily applied. After such an external magnetic field is applied, the magnetization 53m of the free layer 53 can be oriented in an arbitrary direction among the first direction and the second direction. In other words, after such an external magnetic field is applied, the stable state of the free layer 53 may change from one of the first state and the second state to the other.

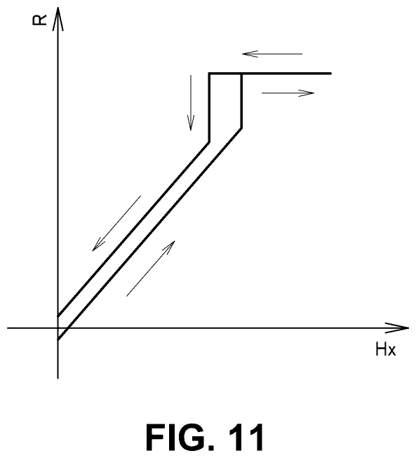

FIG. 11 is an explanatory diagram showing a relationship between the strength Hx of the magnetic field component MFx and the resistance value of the MR element 50. In FIG. 11, the horizontal axis represents the strength Hx of the magnetic field component MFx, and the vertical axis represents a resistance value R of the MR element 50. In FIG. 11, the arrows represent the tendency of the change of the resistance value when the strength Hx changes. FIG. 11 schematically shows the resistance value of the MR element 50 in a case in which the strength Hx is increased until the free layer 53 is magnetically saturated, and then the strength Hx is reduced, when the stable state of the free layer 53 changes from one of the first state and the second state to the other. As shown in FIG. 11, the MR element 50 has a resistance value change characteristic where the resistance value of the MR element 50 changes in accordance with the stable state of the free layer 53, under the same strength Hx.

Here, a resistance change amount ΔR is defined as a parameter associated with the resistance value change characteristic. The resistance change amount ΔR is a parameter defined for each of the MR elements 50. In the example embodiment, the resistance change amount ΔR is defined as a value obtained by subtracting the resistance value in a state (for example, the second state) of the free layer 53, which is different from the current state (for example, the first state), from the current resistance value, when the strength Hx of the magnetic field component MFx is set to a specific strength (for example, zero).

Ideally, the resistance change amount ΔR is zero. However, due to the dispersion of the direction of the magnetization 51ma described above, the resistance change amount ΔR may not be zero. The dispersion of the direction of the magnetization 51ma may differ for each of the MR elements 50. Thus, the resistance change amount ΔR may differ for each of the MR elements 50.

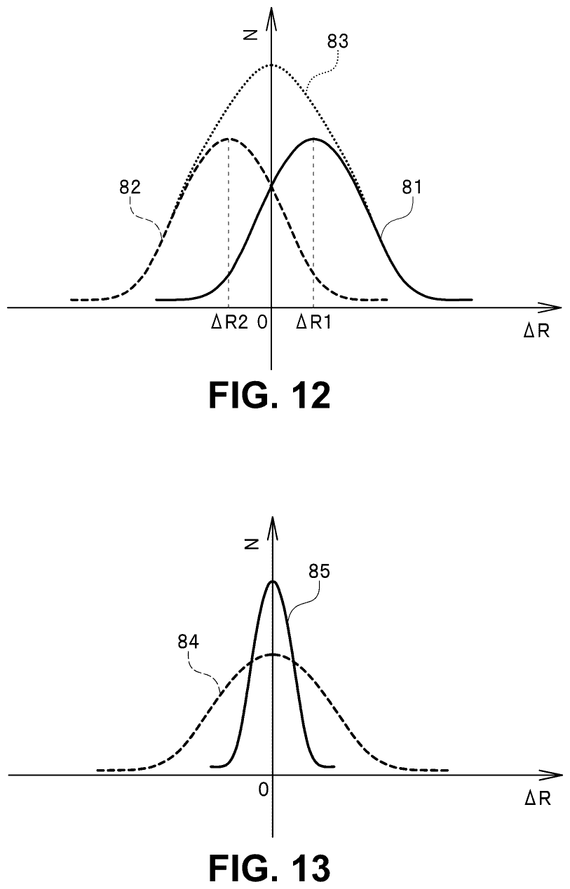

FIG. 12 is an explanatory diagram showing a statistical distribution of the resistance change amount ΔR. In FIG. 12, the horizontal axis represents the resistance change amount ΔR, and the vertical axis represents the number N of MR elements 50. Hereinafter, the MR element 50 in which the current state of the free layer 53 is the first state is referred to as a first MR element 50A, and the MR element 50 in which the current state of the free layer 53 is the second state is referred to as a second MR element 50B. In FIG. 12, the curved line denoted with the reference numeral 81 represents a statistical distribution (first distribution) of the resistance change amount ΔR of a first group being a group of the plurality of first MR elements 50A. The curved line denoted with the reference numeral 82 represents a statistical distribution (second distribution) of the resistance change amount ΔR of a second group being a group of the plurality of second MR elements 50B. The reference numeral 83 represents a statistical distribution (third distribution) of the resistance change amount ΔR of a third group being a group including the first MR element 50A and the second MR element 50B.

As shown in FIG. 12, the first group has a characteristic where the statistical distribution of the resistance change amount ΔR forms the first distribution 81 centered on a first value ΔR1. The second group has a characteristic where the statistical distribution of the resistance change amount ΔR forms the second distribution 82 centered on a second value ΔR2. The first value ΔR1 may be an average value of the resistance change amounts ΔR of the first group. Similarly, the second value ΔR2 may be an average value of the resistance change amounts ΔR of the second group.

FIG. 12 shows an example in which it is assumed that the first value ΔR1 is a positive value, the second value ΔR2 is a negative value, and ΔR2 is equal to or approximately equal to −ΔR1. The following description is based on the assumption shown in FIG. 12.

The third group has a characteristic where the statistical distribution of the resistance change amount ΔR forms the third distribution 83 centered on a third value between the first value ΔR1 and the second value ΔR2. The third value may be an average value of the resistance change amounts ΔR of the third group. The third value is a value (ideally, zero) less than each of an absolute value |ΔR1| of the first value ΔR1 and an absolute value |ΔR2| of the second value ΔR2.

In the example embodiment, the first resistor section R1 to the fourth resistor section R4 are configured based on the characteristic of the third group given above. Each of the first resistor section R1 to the fourth resistor section R4 includes the plurality of first MR elements 50A and the plurality of second MR elements 50B. The plurality of first MR elements 50A and the plurality of second MR elements 50B that form the first resistor section R1 may be arranged in a mixed manner in the element layout region A1 (see FIG. 1), and may be electrically connected to each other. In the first resistor section R1, the total number of the first MR elements 50A and the plurality of second MR elements 50B may be an even number.

The description on the first resistor section R1 given above is also applied to the second resistor section R2 to the fourth resistor section R4. The description on the first resistor section R1 given above is applied to the second resistor section R2 by replacing the first resistor section R1 and the element layout region A1 with the second resistor section R2 and the element layout region A2, respectively. The description on the first resistor section R1 given above is applied to the third resistor section R3 by replacing the first resistor section R1 and the element layout region A1 with the third resistor section R3 and the element layout region A3, respectively. The description on the first resistor section R1 given above is applied to the fourth resistor section R4 by replacing the first resistor section R1 and the element layout region A1 with the fourth resistor section R4 and the element layout region A4, respectively.

Next, operations and effects of the magnetic sensor 1 according to the example embodiment are described. As described above, in the example embodiment, in the first resistor section R1 to the fourth resistor section R4, the plurality of first MR elements 50A and the plurality of second MR elements 50B are electrically connected to each other. With this, according to the example embodiment, variation in characteristics caused by the direction of the magnetization 53m of the free layer 53 can be suppressed. The effect is described below in detail.

When the external magnetic field that magnetically saturates the free layer 53 is temporarily applied to the plurality of first MR elements 50A of the first resistor section R1, a first case, a second case, and a third case given below are assumed. The first case is a case in which the stable state of the free layer 53 changes from the first state to the second state in all or almost all the plurality of first MR elements 50A. In the first case, in all or almost all the plurality of second MR elements 50B of the first resistor section R1, the stable state of the free layer 53 changes from the second state to the first state. In other words, in the first case, all or almost all the plurality of first MR elements 50A are switched to the second MR elements 50B and all or almost all the plurality of second MR elements 50B are switched to the first MR elements 50A.

The second case is a case in which the stable state of the free layer 53 changes from the first state to the second state in a certain number of the first MR elements 50A among the plurality of first MR elements 50A. In the second case, the stable state of the free layer 53 changes from the second state to the first state in the same number or the substantially same number of the second MR elements 50B among the plurality of second MR elements 50B of the first resistor section R1, as the number of the first MR elements 50A in which the stable state of the free layer 53 changes from the first state to the second state. In other words, in the second case, the same number of the first MR elements 50A and the same number of the second MR elements 50B are switched.

The third case is a case in which the stable state of the free layer 53 does not change from the first state in all or almost all the plurality of first MR elements 50A. In the third case, the stable state of the free layer 53 does not change from the second state in all or almost all the plurality of second MR elements 50B of the first resistor section R1.

As described above, in any of the first case to the third case, ideally, in the entire first resistor section R1, the number of the plurality of first MR elements 50A and the number of the plurality of second MR elements 50B remain constant or nearly constant after and before the external magnetic field that magnetically saturates the free layer 53 is temporarily applied. In the example embodiment, the stable state of the free layer 53 is controlled, and thus the number of the plurality of first MR elements 50A and the number of the plurality of second MR elements 50B are controlled. With this, in the example embodiment, as compared to a case in which the stable state of the free layer 53 is not controlled, both the change of the number of the plurality of first MR elements 50A and the change of the number of the plurality of second MR elements 50B are reduced. Therefore, in the example embodiment, the change in the statistical distribution of the resistance change amount ΔR of the plurality of first MR elements 50A and the plurality of second MR elements 50B that form the first resistor section R1 is reduced after and before the external magnetic field that magnetically saturates the free layer 53 is temporarily applied. Thus, in the example embodiment, the change of the average value of the resistance change amounts ΔR of the plurality of first MR elements 50A and the plurality of second MR elements 50B that form the first resistor section R1 is also reduced after and before the external magnetic field that magnetically saturates the free layer 53 is temporarily applied.

The average value of the resistance change amounts ΔR of the plurality of first MR elements 50A and the plurality of second MR elements 50B that form the first resistor section R1 is associated with the change amount of the resistance value of the first resistor section R1 when the external magnetic field that magnetically saturates the free layer 53 is temporarily applied. Specifically, the change amount of the resistance value of the first resistor section R1 is reduced as the average value of the resistance change amounts ΔR is reduced. Therefore, according to the example embodiment, the change amount of the resistance value of the first resistor section R1 can be reduced.

The description on the first resistor section R1 given above is also applied to the second resistor section R2 to the fourth resistor section R4. Therefore, according to the example embodiment, the change amount of the resistance value of each of the second resistor section R2 to the fourth resistor section R4 can be reduced.

According to the example embodiment, the change amount of the resistance value of each of the first resistor section R1 to the fourth resistor section R4 can be reduced. Thus, it is possible to reduce a change amount of at least one detection signal, which is obtained after and before the external magnetic field that magnetically saturates the free layer 53 is temporarily applied and is obtained when the strength Hx of the magnetic field component MFx is the specific strength. In this manner, according to the example embodiment, variation in characteristics caused by the direction of the magnetization 53m of the free layer 53 can be suppressed.

Note that the number of the MR elements 50 forming each of the first resistor section R1 to the fourth resistor section R4 is preferably larger to some extent. Here, similarly to the MR element 50, the resistance change amount ΔR is also defined for a resistance value of an entire arbitrary resistor section among the first resistor section R1 to the fourth resistor section R4. FIG. 13 is an explanatory diagram showing a statistical distribution of the resistance change amount ΔR of one resistor section. The curved line denoted with the reference numeral 84 represents a distribution when the number of the MR elements 50 included in one resistor section is relatively small, and the curved line denoted with the reference numeral 85 represents a distribution when the number of the MR elements 50 included in one resistor section is relatively large. The distribution 85 has a distribution width smaller than the distribution 84. According to the so-called central limit theorem, as the number of the MR elements 50 is increased, the statistical distribution of the resistance change amount ΔR of one resistor section approaches a normal distribution centered on zero, and the standard deviation of the distribution is reduced.

When each of the plurality of MR elements 50 is configured so that the free layer 53 is not magnetically saturated while the strength Hx of the magnetic field component MFx falls within a first range, at least one detection signal changes within a second range while the strength Hx of the magnetic field component MFx changes within the first range. For example, the number of the MR elements 50 forming each of the first resistor section R1 to the fourth resistor section R4 is preferably such a number that a change amount of at least one detection signal, which is obtained after and before the external magnetic field that magnetically saturates the free layer 53 is temporarily applied, and is obtained when the strength Hx of the magnetic field component MFx is the specific strength, is equal to or less than 5% of a difference between a maximum value and a minimum value of the second range, more preferably, such a number that the change amount is equal to or less than 1% thereof.

Next, a control method for the stable state of the free layer 53 is described. As described above, in the example embodiment, the first MR element 50A in which the stable state of the free layer 53 is the first state and the second MR element 50B in which the stable state of the free layer 53 is the second state are mixed. In the example embodiment, the stable state of the free layer 53 is controlled by using at least one method of a plurality of control methods described below.

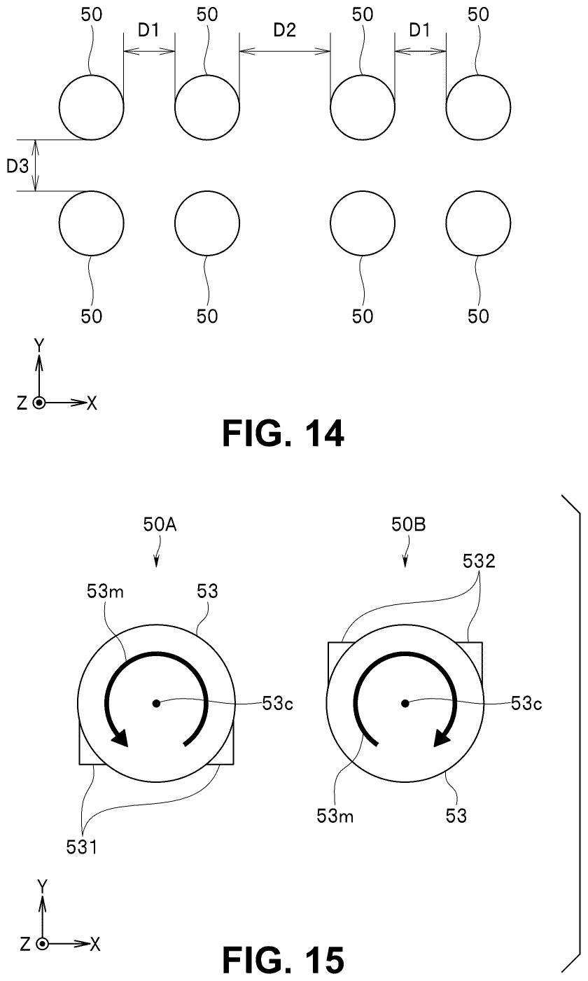

First, with reference to FIG. 14, a first control method is described. FIG. 14 is a plan view showing an example of a layout of the MR elements 50. In FIG. 14, in a direction parallel to the X direction, the two MR elements 50 are adjacent to each other with an interval D1, and the two pairs of the MR elements 50 are adjacent to each other with an interval D2. In a direction parallel to the Y direction, the two MR elements 50 are adjacent to each other with an interval D3.

In the first control method, the interval D1 is set to such an interval that the free layers 53 can be magnetically coupled to act on each other. With this, regardless of the stable state of the free layer 53 of the two MR elements 50, control is performed so that the free layer 53 of one of the two MR elements 50 can be in the first state after the external magnetic field that magnetically saturates the free layer 53 is temporarily applied, and control can be performed so that the free layer 53 of the other one of the two MR elements 50 can be in the second state.

In the first control method, further, the interval D3 is set to be equal or substantially equal to the interval D1. With this, control can be performed so that the stable states of the two MR elements 50 adjacent to each other in the Y direction differ.

In the example embodiment, as viewed in the stacking direction of the magnetization pinned layer 51 and the free layer 53, in other words, the Z direction, the planar shapes of the free layer 53 and each of the MR elements 50 may be circular, or may be substantially circular. Here, the diameter of the planar shape of the MR element 50 is represented by the symbol D, and the film thickness being a dimension of the MR element 50 in the stacking direction is represented by the symbol T. The interval D1 (interval D3) may be equal to or less than an estimation interval defined based on the diameter D and the film thickness T. The estimation interval may be an interval at which the free layers 53 can at least act on each other (a maximum interval at which the free layers 53 can be magnetically coupled to each other to act on each other), and may be an interval in which the strength of the magnetic field acting on the free layer 53 is several to more than ten times that of the geomagnetic field. In one example, an estimation interval X can be expressed in Expression (1) given below by using the diameter D and the film thickness T. Note that, in Expression (1), the estimation interval X is set as an interval in which the strength of the magnetic field acting on the free layer 53 is ten times that of the geomagnetic field.

$$X = 8 \times {D}^{\frac{2}{3}} \times {T}^{\frac{1}{3}} \qquad ( 1 )$$

As expressed in Expression (1), the estimation interval X is proportional to the two-thirds power of the diameter D, and is proportional to the one-third power of the film thickness T. The interval D1 (interval D3) is preferably equal to or less than the estimation interval X. The interval D2 may be equal to the interval D1, or may be equal to or more than the interval D1.

Next, with reference to FIG. 15, a second control method is described. FIG. 15 is a plan view showing the free layer 53 to which a structure for controlling the direction of the magnetization 53m of the free layer 53 is added. In the second control method, the first MR element 50A includes a structure 531 for orienting the magnetization 53m of the free layer 53 in the first direction. The second MR element 50B includes a structure 532 for orienting the magnetization 53m of the free layer 53 in the second direction. Each of the structures 531 and 532 may be at least one protruding structure that is added to the outer edge of the free layer 53. The structures 531 and 532 may satisfy a requirement where the planar shape of the structure 532 is obtained by rotating the planar shape of the structure 531 by 180 degrees about the magnetic vortex structure center 53c.

In the MR element 50 including the structure 531, the stable state of the free layer 53 can be in the first state after the external magnetic field that magnetically saturates the free layer 53 is temporarily applied. In the MR element 50 including the structure 532, the stable state of the free layer 53 can be in the second state after the external magnetic field that magnetically saturates the free layer 53 is temporarily applied.

Note that the function of each of the structures 531 and 532 may not be absolute, and may be relative so that the direction of the magnetization 53m is decided depending on the direction of the external magnetic field.

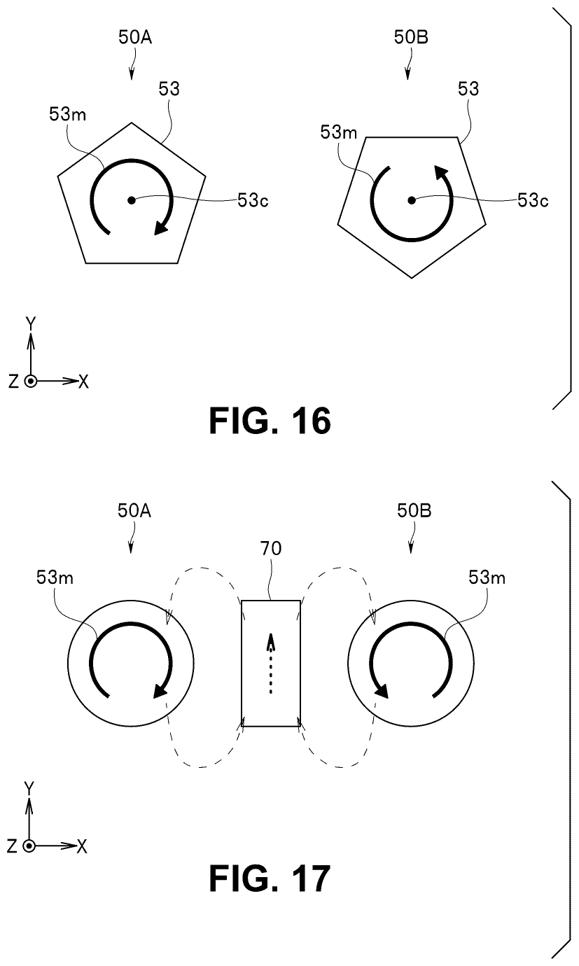

Next, with reference to FIG. 16, a third control method is described. FIG. 16 is a plan view showing the free layer 53 that has a planar shape that can control the direction of the magnetization 53m of the free layer 53. In the third control method, the free layer 53 has a planar shape that can control the direction of the magnetization 53m of the free layer 53, and the planar shape satisfies the following requirement. In other words, the third control method, the first MR element 50A and the second MR element 50B satisfy a requirement where the planar shape of the second MR element 50B is obtained by rotating the planar shape of the first MR element 50A by 180 degrees about the magnetic vortex structure center 53c. In the example shown in FIG. 16, the planar shape of each of the first MR element 50A and the second MR element 50B is a pentagon.

Note that the function of the planar shape of each of the first MR element 50A and the second MR element 50B may not be absolute, and may be relative so that the direction of the magnetization 53m is decided depending on the direction of the external magnetic field. The planar shape of each of the first MR element 50A and the second MR element 50B may be a polygon other than a pentagon (for example, a polygon having twenty-four or more sides).

Next, with reference to FIG. 17, a fourth control method is described. FIG. 17 is a plan view showing the MR element 50 and a first structure that controls the direction of the magnetization 53m of the free layer 53. In the fourth control method, the magnetic sensor 1 may include a first structure 70 that controls the direction of the magnetization 53m of the free layer 53. The first structure 70 may be a yoke that is arranged between the two MR elements 50 and is formed of a magnetic material.

In the fourth control method, when the external magnetic field that magnetically saturates the free layer 53 is temporarily applied to the MR element 50 and the first structure 70, the first structure 70 is magnetized. FIG. 17 shows an example in which the external magnetic field in the Y direction is applied. With this, the magnetic field that controls the direction of the magnetization 53m of the free layer 53 is generated from the first structure 70. With this, the stable state of the free layer 53 of one of the two MR elements 50 can be in the first state, and the stable state of the free layer 53 of the other one of the two MR elements 50 can be in the second state.

Note that the function of the first structure 70 may not be absolute, and may be relative so that the direction of the magnetization 53m is decided depending on the direction of the external magnetic field.

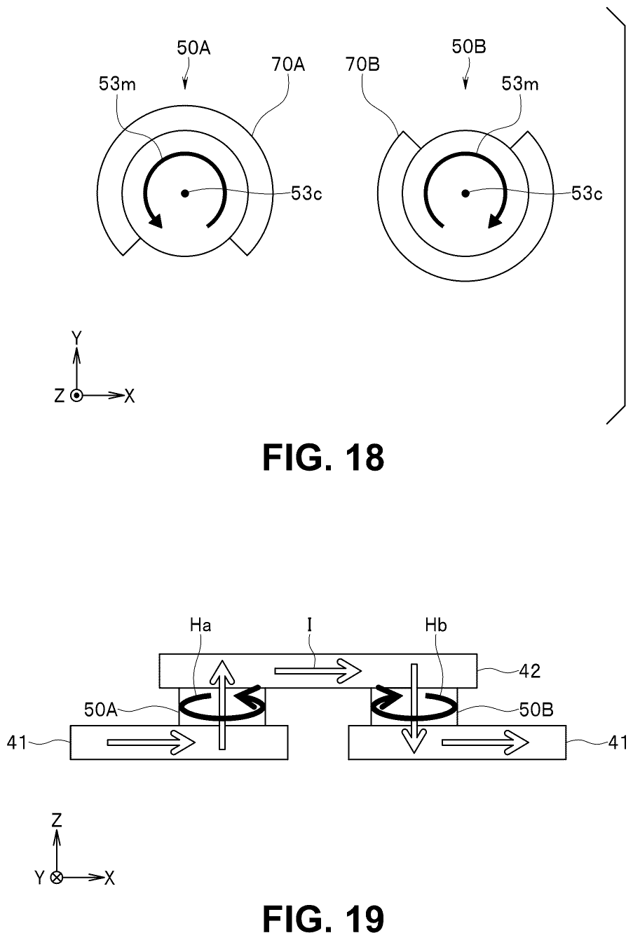

Next, with reference to FIG. 18, a fifth control method is described. FIG. 18 is a plan view showing the MR element 50 and a second structure that controls the direction of the magnetization 53m of the free layer 53. In the fifth control method, the magnetic sensor 1 includes the second structures 70A and 70B that control the direction of the magnetization 53m of the free layer 53. The second structures 70A may be formed of a magnetic material, may be a yoke provided in the periphery of the free layer 53, and may have a structure for orienting the magnetization 53m of the free layer 53 in the first direction. The second structures 70B may be formed of a magnetic material, may be a yoke provided in the periphery of the free layer 53, and may have a structure for orienting the magnetization 53m of the free layer 53 in the second direction. The second structures 70A and 70B may satisfy a requirement where the planar shape of the second structures 70B is obtained by rotating the planar shape of the second structures 70A by 180 degrees about the magnetic vortex structure center 53c.

Note that the function of each of the second structures 70A and 70B may not be absolute, and may be relative so that the direction of the magnetization 53m is decided depending on the direction of the external magnetic field.

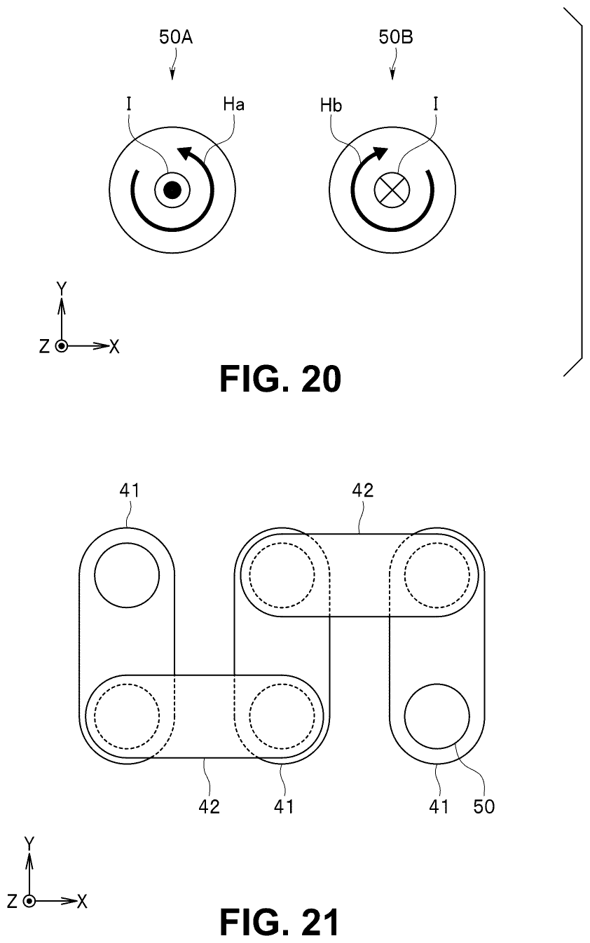

Next, with reference to FIG. 19 and FIG. 20, a sixth control method is described. FIG. 19 is an explanatory diagram schematically showing a direction of an electric current flowing through the MR element 50. FIG. 20 is an explanatory diagram schematically showing a magnetic field generated due to the electric current flowing through the MR element 50. In the example embodiment, a direction of the electric current I flowing through the MR element 50 is a direction extending from the lower electrode 41 toward the upper electrode 42, in other words, the Z direction, and is a direction extending from the upper electrode 42 toward the lower electrode 41, in other words, the −Z direction.

When the electric current I in the Z direction flows through the MR element 50, a magnetic field Ha that is generated due to the electric current I is generated in the MR element 50. The magnetic field Ha is generated in the first direction (the counterclockwise direction in FIG. 20) around the magnetic vortex structure center 53c, as viewed in the Z direction. When the electric current I in the −Z direction flows through the MR element 50, a magnetic field Hb that is generated due to the electric current I is generated in the MR element 50. The magnetic field Hb is generated in the second direction (the clockwise direction in FIG. 20) opposite to the first direction around the magnetic vortex structure center 53c, as viewed in the Z direction. In the sixth control method, the stable state of the free layer 53 can be in the first state due to the magnetic field Ha, and the stable state of the free layer 53 can be in the second state due to the magnetic field Hb.

In the sixth control method, in particular, the number of the MR elements 50 is an even number in each of the first resistor section R1 to the fourth resistor section R4, and the number of the MR elements 50 through which the electric current I flows in the Z direction and the number of the MR elements 50 through which the electric current I flows in the −Z direction are equal to each other. With this, the number of the first MR elements 50A and the number of the second MR elements 50B can be equal to each other.

In the sixth control method, in particular, the first MR element 50A and the second MR element 50B may be directly connected to one lower electrode 41, and the first MR element 50A and the second MR element 50B may be directly connected to one upper electrode 42.

### Modification Example

Next, a first modification example to a third modification example of the magnetic sensor 1 according to the example embodiment are described. First, with reference to FIG. 21, the first modification example is described. FIG. 21 is a plan view showing the first modification example of the magnetic sensor 1. In the first modification example, the plurality of lower electrodes 41 and the plurality of upper electrodes 42 connect the plurality of MR elements 50 so that the shape of the plurality of MR elements 50, the plurality of lower electrodes 41, and the plurality of upper electrodes 42 as viewed from the top has a meander shape. In the example shown in FIG. 21, each of the plurality of lower electrodes 41 extends in a direction parallel to the Y direction, and each of the plurality of upper electrodes 42 extends in a direction parallel to the X direction. However, the extension direction of each of the plurality of lower electrodes 41 and the extension direction of each of the plurality of upper electrodes 42 are not limited to the example shown in FIG. 21, and are only required to extend in two directions intersecting with each other.

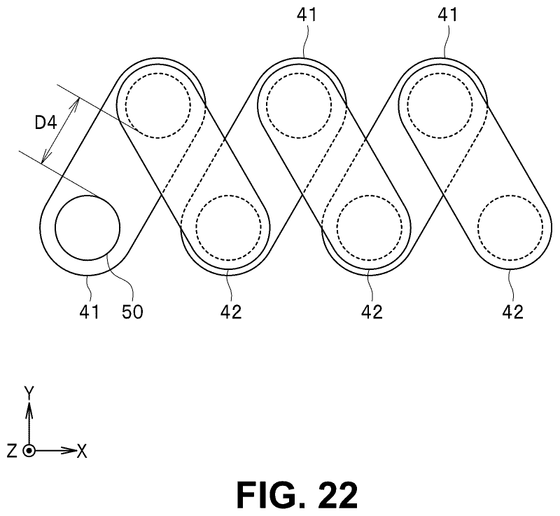

Next, with reference to FIG. 22, the second modification example is described. FIG. 22 is a plan view showing the second modification example of the magnetic sensor 1. In the second modification example, the plurality of MR elements 50 are arranged so that an interval between the two MR elements 50 that are adjacent to each other in an arbitrary direction is D4. Specifically, the plurality of MR elements 50 are arranged so that a shape formed by connecting the centroids of the three MR elements 50 arranged closest to each other is an equilateral triangle as viewed in the Z direction. The comparison is made under a condition that the same area of the element layout region is provided. According to the second modification example, the number of the MR elements can be increased by approximately 15% as compared to a case in which a plurality of MR elements are arrayed in a grid pattern in direction parallel to the X direction and a direction parallel to the Y direction.

In the example shown in FIG. 22, the lower electrode 41 extends in a direction parallel to a direction obtained by rotating the X direction toward the Y direction by 60 degrees. The upper electrode 42 extends in a direction parallel to a direction obtained by rotating the Y direction toward the −X direction by 30 degrees.

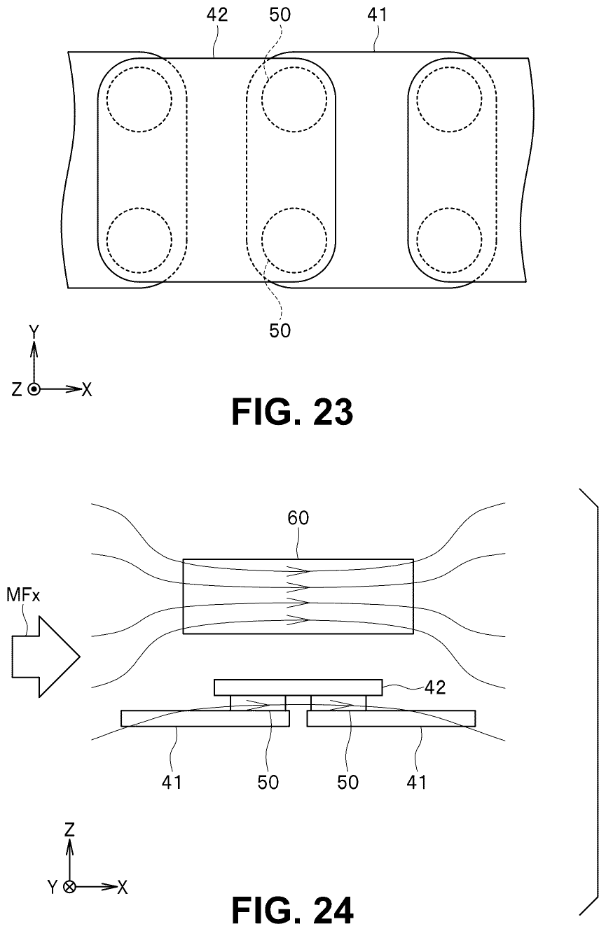

Next, with reference to FIG. 23, the third modification example is described. FIG. 23 is a plan view showing the third modification example of the magnetic sensor 1. In the third modification example, the plurality of MR elements 50 may include a plurality of pairs each including the two MR elements 50. The plurality of pairs are connected in series to each other by the plurality of lower electrodes 41 and the plurality of upper electrodes 42. In other words, the two MR elements 50 of each of the plurality of pairs are connected in parallel to each other by one lower electrode 41 and one upper electrode 42.

### Second Example Embodiment

Next, with reference to FIG. 24, a second example embodiment of the disclosure is described. FIG. 24 is a side view showing an MR element and a shield in the example embodiment. The magnetic sensor 1 according to the example embodiment may include a shield 60 formed of a magnetic material. The shield 60 may be arranged to cover the first resistor section R1 to the fourth resistor section R4 (see FIG. 1). The shield 60 may be one magnetic body, or may be a plurality of divided magnetic bodies.

The shield 60 is configured to reduce the strength of the applied magnetic field applied to the plurality of MR elements 50. FIG. 24 shows an example in which the magnetic field component MFx is applied to the magnetic sensor 1. In the example shown in FIG. 24, the magnetic field component MFx in an attenuated state is applied to the magnetic sensor 1.

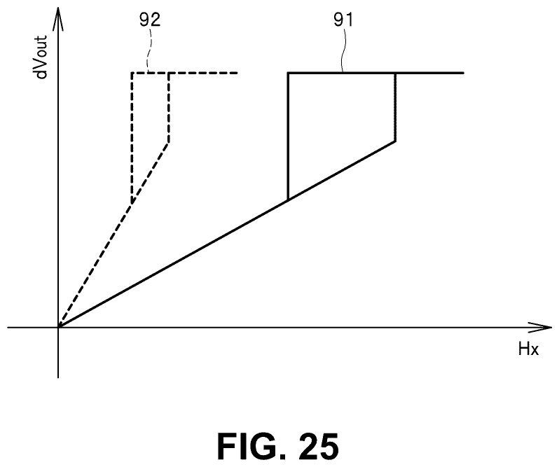

Next, with reference to FIG. 25, the effects of the shield 60 are described. FIG. 25 is a characteristic diagram showing a relationship between the strength Hx of the magnetic field component MFx and the detection signal. In FIG. 25, the horizontal axis represents the strength Hx, and the vertical axis represents a magnitude of the detection signal. In particular, FIG. 25 shows, as a magnitude of the detection signal, a potential difference dVout between the first output terminal 13 and the second output terminal 14 (see FIG. 2). The reference numeral 91 represents a relationship between the strength Hx and the detection signal when the shield 60 is provided, and the reference numeral 92 represents a relationship between the strength Hx and the detection signal when the shield 60 is not provided.

As shown in FIG. 25, according to the example embodiment, due to the shield 60, the range (first range) within which the strength Hx of the magnetic field component MFx can change without magnetically saturating the free layer 53 can be increased.

The configuration, operations, and effects of the example embodiment are otherwise the same as those of the first example embodiment.

Note that the disclosure is not limited to each of the foregoing example embodiments, and various modifications may be made thereto. For example, as long as the requirements of the appended claims are met, the layout of the first to fourth resistor sections R1 to R4 is not limited to the example shown in each of the example embodiments, and it is optional.

As described above, a magnetic sensor according to an embodiment of a first aspect of the disclosure is configured to detect a magnetic field of a detection target to generate a detection signal, and includes a plurality of first magnetoresistive elements and a plurality of second magnetoresistive elements. The plurality of first magnetoresistive elements and the plurality of second magnetoresistive elements are electrically connected to each other. Each of the plurality of first magnetoresistive elements and the plurality of second magnetoresistive elements includes a magnetization pinned layer in which a direction of magnetization is fixed and a free layer configured to have a magnetic vortex structure and move a center of the magnetic vortex structure in accordance with an applied magnetic field, and has a resistance value change characteristic where a resistance value changes in accordance with a stable state of the magnetic vortex structure, under the same strength of the applied magnetic field. A first group being a group of the plurality of first magnetoresistive elements has a characteristic where a statistical distribution of a resistance change amount forms a first distribution centered on a first value, the resistance change amount being a parameter associated with the resistance value change characteristic. A second group being a group of the plurality of second magnetoresistive elements has a characteristic where the statistical distribution of the resistance change amount forms a second distribution centered on a second value different from the first value. A third group being a group including the plurality of first magnetoresistive elements and the plurality of second magnetoresistive elements has a characteristic where the statistical distribution of the resistance change amount forms a third distribution centered on a third value between the first value and the second value.

In the magnetic sensor according to the embodiment of the disclosure, each of the plurality of first magnetoresistive elements and the plurality of second magnetoresistive elements may be configured so that the free layer is not magnetically saturated when a strength of the magnetic field being the detection target falls within a first range. The detection signal may change within a second range when the strength of the magnetic field being the detection target changes within the first range. The third group may have a characteristic where, as the number of the magnetoresistive elements included in the third group is increased, a statistical distribution of the resistance change amount of a resistor section approaches a normal distribution, and a standard deviation of the distribution is reduced, the resistor section being configured by electrically connecting the magnetoresistive elements included in the third group to each other. The number of the magnetoresistive elements included in the third group may be defined as a number at which a change amount is equal to or less than 5% of a difference between a maximum value and a minimum value of the second range, the change amount being a change amount of the detection signal before and after temporary application of an external magnetic field that magnetically saturates the free layer to the plurality of first magnetoresistive elements and the plurality of second magnetoresistive elements and a change amount of the detection signal when the strength of the magnetic field being the detection target is a specific strength within the first range.

In the magnetic sensor according to the embodiment of the disclosure, the free layer of each of the plurality of first magnetoresistive elements may be stable while a direction of magnetization of the free layer is along a first direction around the center of the magnetic vortex structure as viewed in a stacking direction of the magnetization pinned layer and the free layer. The free layer of each of the plurality of second magnetoresistive elements may be stable while a direction of magnetization of the free layer is along a second direction around the center of the magnetic vortex structure as viewed in the stacking direction of the magnetization pinned layer and the free layer, the second direction being opposite to the first direction. The magnetization of the free layer may be capable of being oriented in any of the first direction and the second direction after an external magnetic field that magnetically saturates the free layer is temporarily applied to the free layer. Each of the plurality of first magnetoresistive elements may have a first structure for orienting the magnetization of the free layer in the first direction. Each of the plurality of second magnetoresistive elements may have a second structure for orienting the magnetization of the free layer in the second direction. The magnetic sensor of the first aspect of the disclosure may further include a plurality of structures each configured to orient the magnetization of the free layer in the first direction or the second direction.

In the magnetic sensor according to the embodiment of the disclosure, the third group may include a plurality of element arrays. Each of the plurality of element arrays may include a plurality of magnetoresistive elements connected in series to each other. The plurality of element arrays may be connected in parallel to each other. The magnetic sensor of the first aspect of the disclosure may further include an electrode. The plurality of first magnetoresistive elements may include a specific first magnetoresistive element directly connected to the electrode. The plurality of second magnetoresistive elements may include a specific second magnetoresistive element directly connected to the electrode.

In the magnetic sensor according to the embodiment of the disclosure, the third group may include a plurality of pairs of magnetoresistive elements connected in parallel to each other.

In the magnetic sensor according to the embodiment of the disclosure, the plurality of first magnetoresistive elements may include a specific first magnetoresistive element. The plurality of second magnetoresistive elements may include a specific second magnetoresistive element adjacent to the specific first magnetoresistive element with an interval. A planar shape of the free layer may be circular as viewed in a stacking direction of the magnetization pinned layer and the free layer. Each of the specific first magnetoresistive element and the specific second magnetoresistive element may have a diameter of a planar shape as viewed in the stacking direction and a film thickness being a dimension in the stacking direction. The interval between the specific first magnetoresistive element and the specific second magnetoresistive element may be equal to or less than an estimation interval defined based on the diameter and the film thickness.

The magnetic sensor according to the embodiment of the disclosure may further include a substrate including an element layout region. The plurality of first magnetoresistive elements and the plurality of second magnetoresistive elements may be arranged in a mixed manner in the element layout region.

In the magnetic sensor according to the embodiment of the disclosure, a total of the number of the plurality of first magnetoresistive elements and the number of the plurality of second magnetoresistive elements may be an even number.

In the magnetic sensor according to the embodiment of the disclosure, among the magnetoresistive elements included in the third group, the number of magnetoresistive elements through which an electric current flows in one direction parallel to a stacking direction of the magnetization pinned layer and the free layer may be equal to the number of magnetoresistive elements through which an electric current flows in a direction opposite to the one direction.

In the magnetic sensor according to the embodiment of the first aspect of the disclosure, the magnetization of the magnetization pinned layer may include a plurality of components with directions different from each other.

The magnetic sensor according to the embodiment of the disclosure may further include a shield configured to reduce the strength of the applied magnetic field.

A magnetic sensor according to an embodiment of a second aspect of the disclosure is configured to detect a magnetic field of a detection target to generate a detection signal, and includes a plurality of magnetoresistive elements. Each of the plurality of magnetoresistive elements includes a magnetization pinned layer in which a direction of magnetization is fixed and a free layer configured to have a magnetic vortex structure and move a center of the magnetic vortex structure in accordance with an applied magnetic field, and has a resistance value change characteristic where a resistance value changes in accordance with a stable state of the magnetic vortex structure, under the same strength of the applied magnetic field. A group of the plurality of magnetoresistive elements has a characteristic where a statistical distribution of a resistance change amount forms a distribution centered on a specific value, the resistance change amount being a parameter associated with the resistance value change characteristic. Each of the plurality of magnetoresistive elements is configured so that the free layer is not magnetically saturated when the strength of the magnetic field being the detection target falls within a first range. The detection signal changes within a second range when a strength of the magnetic field being the detection target changes within the first range. The group has a characteristic where, as the number of the plurality of magnetoresistive elements is increased, a statistical distribution of the resistance change amount of a resistor section approaches a normal distribution, and a standard deviation of the distribution is reduced, the resistor section being configured by electrically connecting the plurality of magnetoresistive elements to each other. The number of the plurality of magnetoresistive elements is defined as a number at which a change amount is equal to or less than 5% of a difference between a maximum value and a minimum value of the second range, the change amount being a change amount of the detection signal before and after temporary application of an external magnetic field that magnetically saturates the free layer to the plurality of magnetoresistive elements and a change amount of the detection signal when the strength of the magnetic field being the detection target is a specific strength within the first range.

In the magnetic sensor of the first aspect and the second aspect of the disclosure, the statistical distribution of the resistance change amount being the parameter associated with the resistance value change characteristic has a specific characteristic. With this, according to the disclosure, variation in characteristics caused by a direction of magnetization of a free layer can be suppressed.

Obviously, various aspects and modification examples of the disclosure can be practiced in the light of the foregoing descriptions. Thus, within the scope of the appended claims and equivalents thereof, the disclosure can be practiced in embodiments other than the foregoing example embodiments.

1. A magnetic sensor configured to detect a magnetic field of a detection target to generate a detection signal, the magnetic sensor comprising:
a plurality of first magnetoresistive elements; and
a plurality of second magnetoresistive elements, wherein
the plurality of first magnetoresistive elements and the plurality of second magnetoresistive elements are electrically connected to each other,
each of the plurality of first magnetoresistive elements and the plurality of second magnetoresistive elements includes a magnetization pinned layer in which a direction of magnetization is fixed and a free layer configured to have a magnetic vortex structure and move a center of the magnetic vortex structure in accordance with an applied magnetic field, and has a resistance value change characteristic where a resistance value changes in accordance with a stable state of the magnetic vortex structure, under the same strength of the applied magnetic field,
a first group being a group of the plurality of first magnetoresistive elements has a characteristic where a statistical distribution of a resistance change amount forms a first distribution centered on a first value, the resistance change amount being a parameter associated with the resistance value change characteristic,
a second group being a group of the plurality of second magnetoresistive elements has a characteristic where the statistical distribution of the resistance change amount forms a second distribution centered on a second value different from the first value, and
a third group being a group including the plurality of first magnetoresistive elements and the plurality of second magnetoresistive elements has a characteristic where the statistical distribution of the resistance change amount forms a third distribution centered on a third value between the first value and the second value.

2. The magnetic sensor according to claim 1, wherein
each of the plurality of first magnetoresistive elements and the plurality of second magnetoresistive elements is configured so that the free layer is not magnetically saturated when a strength of the magnetic field being the detection target falls within a first range,
the detection signal changes within a second range when the strength of the magnetic field being the detection target changes within the first range,
the third group has a characteristic where, as the number of the magnetoresistive elements included in the third group is increased, a statistical distribution of the resistance change amount of a resistor section approaches a normal distribution, and a standard deviation of the distribution is reduced, the resistor section being configured by electrically connecting the magnetoresistive elements included in the third group to each other, and
the number of the magnetoresistive elements included in the third group is defined as a number at which a change amount is equal to or less than 5% of a difference between a maximum value and a minimum value of the second range, the change amount being a change amount of the detection signal before and after temporary application of an external magnetic field that magnetically saturates the free layer to the plurality of first magnetoresistive elements and the plurality of second magnetoresistive elements and a change amount of the detection signal when the strength of the magnetic field being the detection target is a specific strength within the first range.

3. The magnetic sensor according to claim 1, wherein
the free layer of each of the plurality of first magnetoresistive elements is stable while a direction of magnetization of the free layer is along a first direction around the center of the magnetic vortex structure as viewed in a stacking direction of the magnetization pinned layer and the free layer, and
the free layer of each of the plurality of second magnetoresistive elements is stable while a direction of magnetization of the free layer is along a second direction around the center of the magnetic vortex structure as viewed in the stacking direction of the magnetization pinned layer and the free layer, the second direction being opposite to the first direction.

4. The magnetic sensor according to claim 3, wherein
the magnetization of the free layer is capable of being oriented in any of the first direction and the second direction after an external magnetic field that magnetically saturates the free layer is temporarily applied to the free layer.

5. The magnetic sensor according to claim 3, wherein
each of the plurality of first magnetoresistive elements has a first structure for orienting the magnetization of the free layer in the first direction, and
each of the plurality of second magnetoresistive elements has a second structure for orienting the magnetization of the free layer in the second direction.

6. The magnetic sensor according to claim 3, further comprising:
a plurality of structures each configured to orient the magnetization of the free layer in the first direction or the second direction.

7. The magnetic sensor according to claim 1, wherein
the third group includes a plurality of element arrays, and
each of the plurality of element arrays includes a plurality of magnetoresistive elements connected in series to each other.

8. The magnetic sensor according to claim 7, wherein
the plurality of element arrays are connected in parallel to each other.

9. The magnetic sensor according to claim 7, further comprising:
an electrode, wherein
the plurality of first magnetoresistive elements includes a specific first magnetoresistive element directly connected to the electrode, and
the plurality of second magnetoresistive elements includes a specific second magnetoresistive element directly connected to the electrode.

10. The magnetic sensor according to claim 1, wherein
the third group includes a plurality of pairs of magnetoresistive elements connected in parallel to each other.

11. The magnetic sensor according to claim 1, wherein
the plurality of first magnetoresistive elements includes a specific first magnetoresistive element, and
the plurality of second magnetoresistive elements includes a specific second magnetoresistive element adjacent to the specific first magnetoresistive element with an interval.

12. The magnetic sensor according to claim 11, wherein
a planar shape of the free layer is circular as viewed in a stacking direction of the magnetization pinned layer and the free layer,
each of the specific first magnetoresistive element and the specific second magnetoresistive element has a diameter of a planar shape as viewed in the stacking direction and a film thickness being a dimension in the stacking direction, and
the interval between the specific first magnetoresistive element and the specific second magnetoresistive element is equal to or less than an estimation interval defined based on the diameter and the film thickness.

13. The magnetic sensor according to claim 1, further comprising:
a substrate including an element layout region, wherein
the plurality of first magnetoresistive elements and the plurality of second magnetoresistive elements are arranged in a mixed manner in the element layout region.

14. The magnetic sensor according to claim 1, wherein
a total of the number of the plurality of first magnetoresistive elements and the number of the plurality of second magnetoresistive elements is an even number.

15. The magnetic sensor according to claim 1, wherein
among the magnetoresistive elements included in the third group, the number of magnetoresistive elements through which an electric current flows in one direction parallel to a stacking direction of the magnetization pinned layer and the free layer is equal to the number of magnetoresistive elements through which an electric current flows in a direction opposite to the one direction.

16. The magnetic sensor according to claim 1, wherein
the magnetization of the magnetization pinned layer includes a plurality of components with directions different from each other.

17. The magnetic sensor according to claim 1, further comprising:
a shield configured to reduce the strength of the applied magnetic field.

18. A magnetic sensor configured to detect a magnetic field of a detection target to generate a detection signal, the magnetic sensor comprising:
a plurality of magnetoresistive elements, wherein
each of the plurality of magnetoresistive elements includes a magnetization pinned layer in which a direction of magnetization is fixed and a free layer configured to have a magnetic vortex structure and move a center of the magnetic vortex structure in accordance with an applied magnetic field, and has a resistance value change characteristic where a resistance value changes in accordance with a stable state of the magnetic vortex structure, under the same strength of the applied magnetic field,
a group of the plurality of magnetoresistive elements has a characteristic where a statistical distribution of a resistance change amount forms a distribution centered on a specific value, the resistance change amount being a parameter associated with the resistance value change characteristic,
each of the plurality of magnetoresistive elements is configured so that the free layer is not magnetically saturated when the strength of the magnetic field being the detection target falls within a first range,
the detection signal changes within a second range when the strength of the magnetic field being the detection target changes within the first range,
the group has a characteristic where, as the number of the plurality of magnetoresistive elements is increased, a statistical distribution of the resistance change amount of a resistor section approaches a normal distribution, and a standard deviation of the distribution is reduced, the resistor section being configured by electrically connecting the plurality of magnetoresistive elements to each other, and
the number of the plurality of magnetoresistive elements is defined as a number at which a change amount is equal to or less than 5% of a difference between a maximum value and a minimum value of the second range, the change amount being a change amount of the detection signal before and after temporary application of an external magnetic field that magnetically saturates the free layer to the plurality of magnetoresistive elements and a change amount of the detection signal when the strength of the magnetic field being the detection target is a specific strength within the first range.
